(19) United States
(12) Patent Application Publication
(10) Pub. No.: US 2025/0239545 A1
(43) Pub. Date: Jul. 24, 2025

(54) ELECTRICAL CONTACTS AND SYSTEMS AND TECHNIQUES FOR FORMING ELECTRICAL CONTACTS

(71) Applicant: Honeywell International Inc., Charlotte, NC (US)

(72) Inventors: Bryan Roger Seppala, Fridley, MN (US); Jenny Lyn Calubayan, Woodbury, MN (US); Scott Gerald Neidermyer, Prior Lake, MN (US); Matthew Thomas Spurr, Plymouth, MN (US); Michael Monfils, Bloomington, MN (US); Eric E. Vogt, Cody, WY (US); Isaac Scott Dvergsten, Saint Louis Park, MN (US)

(21) Appl. No.: 18/421,743

(22) Filed: Jan. 24, 2024

(51) Int. Cl. H01L 23/00; C25D 5/00; C25D 5/10; C25D 7/12

(52) U.S. Cl. CPC H01L 24/03; C25D 5/10; C25D 5/605; C25D 7/12; H01L 24/05; H01L 24/08; H01L 2224/03462; H01L 2224/05109; H01L 2224/05111; H01L 2224/05139; H01L 2224/05144; H01L 2224/05147; H01L 2224/05155; H01L 2224/05164; H01L 2224/05169; H01L 2224/05171; H01L 2224/05173; H01L 2224/05609; H01L 2224/05611; H01L 2224/05639; H01L 2224/05644; H01L 2224/05647; H01L 2224/05655; H01L 2224/05664; H01L 2224/05669; H01L 2224/05673; H01L 2224/08145

(57) ABSTRACT

An example system includes a plating apparatus and processing circuitry. The plating apparatus may be configured to plate a coating including a plating composition on an electrical contact of a circuit substrate. The processing circuitry may be further configured to cause the plating apparatus to plate a first layer of the coating on the electrical contact of the circuit substrate using a first current density. The processing circuitry may be further configured to plate a second layer of the coating on the first layer using a second current density that is higher than the first current density. The second layer may include a nodular deposit including the plating composition.

### TECHNICAL FIELD

The present disclosure relates to electrical contacts, and to systems and techniques for forming electrical contacts, for example, for integrated circuits and packages.

### BACKGROUND

Integrated circuits include a semiconductor die carrying fabricated electronic features, for example, circuit components and traces. The features may be fabricated by lithography and deposition techniques. Integrated circuits and packages may be electrically connected by electrical contacts, for example, pads, pins, or the like, to other components. For example, an integrated circuit device may be connected to another integrated circuit device, to a printed circuit board, or to some other mount, for example, a socket.

### SUMMARY

In general, the disclosure describes electrical contacts and techniques for forming electrical contacts, for example, for integrated circuits and packages. An electrical contact formed on a non-planar surface may deform in response to strain exerted on a portion of the electrical contact. For example, when the electrical contact on the non-planar surface contacts another electrical contact on another planar or non-planar surface, one or both of the electrical contacts may tend to deform based on the geometry at the interface between the surfaces. In some examples according to the present disclosure, an electrical contact includes a nodular deposit of a plating composition. The nodular deposit may facilitate or promote compliance of the electrical contact, such that the electrical contact exhibits integrity and resistance to separation or breaking from a substrate.

In some examples, a system includes a plating apparatus and processing circuitry. The plating apparatus may be configured to plate a coating including a plating composition on an electrical contact of a circuit substrate. The processing circuitry may be further configured to cause the plating apparatus to plate a first layer of the coating on the electrical contact of the circuit substrate using a first current density. The processing circuitry may be further configured to plate a second layer of the coating on the first layer using a second current density that is higher than the first current density. The second layer may include a nodular deposit including the plating composition.

In some examples, a method includes plating a first layer of a coating including a plating composition on an electrical contact of a circuit substrate using a first current density. The method may further include plating a second layer of the coating on the first layer using a second current density that is higher than the first current density. The second layer may include a nodular deposit including the plating composition.

In some examples, an assembly includes a circuit substrate, and an electrical contact on a surface of the circuit substrate. The electrical contact includes a coating including a plating composition. The coating includes a first layer and a second layer extending from the first layer. The first layer is between the electrical contact and the second layer. The second layer includes a nodular deposit including the plating composition.

The details of one or more examples are set forth in the accompanying drawings and the description below. Other features, objects, and advantages will be apparent from the description and drawings, and from the claims.

### BRIEF DESCRIPTION OF THE FIGURES

The details of one or more examples are set forth in the accompanying drawings and the description below. Other features, objects, and advantages will be apparent from the description and drawings, and from the claims.

FIG. 1 is a block diagram of an example system including a plating apparatus configured to form plating on an assembly including an electrical contact of a circuit substrate.

FIG. 2A is a partial cross-sectional view of an example assembly in a first configuration including an electrical contact and a first layer.

FIG. 2B is a partial cross-sectional view of the assembly of FIG. 2A in a second configuration further including a second layer on the first layer.

FIG. 2C is a partial magnified view of an example coating including the first layer and the second layer of FIG. 2B, the second layer including a nodular deposit.

FIG. 3 is a partial cross-sectional view of an example assembly including an integrated circuit package including a first circuit substrate including a nodular plating bonded to a second circuit substrate including a non-nodular plating.

FIG. 4 is a partial cross-sectional view of an example assembly including an integrated circuit package including a first circuit substrate including a nodular plating bonded to a second circuit substrate including a nodular plating.

FIG. 5 is a block diagram illustrating an example computing device configured to control a plating apparatus.

FIG. 6 is a flowchart representing an example technique for forming electrical contacts, for example, for integrated circuits and packages.

### DETAILED DESCRIPTION

In general, the disclosure describes electrical contacts and techniques for forming electrical contacts, for example, for integrated circuits and packages. Relatively large dies or substrates may define non-planar surfaces, for example, including steps, bends, plateaus, mesas, depressions, inclines, or combinations thereof. Such non-planar features may result from certain processes performed during the course of fabricating wafers, which can cause a die within a wafer to be non-planar or non-flat. Electrical contacts formed on or over non-planar surfaces may resist bonding with electrical contacts formed on or over planar or flat surfaces, resulting in insufficient electrical contact at an interface. For example, gaps may be present between the surfaces along the interface, leading to a poor electrical connection.

The electrical contacts or bond pads may be plated with gold or any other suitable metal or alloy. In some examples, a current density is increased in course of plating. For example, the current density may be maintained at a relatively lower first current density for an initial layer or an initial portion of a layer, and increased to a relatively higher current density for a final layer or final portion of the layer. For example, a higher current density may be used in the last 25% to 75% of a coating thickness. The higher current density may be sufficient to induce plating of a nodular deposit, which is deformable in response to a bond force applied during a bonding process of die to die, die to substrate, or substrate to substrate. Thus, the nodular deposit may promote compliance of the coating plated on the contact, or of the contact as a whole. The nodular deposit may include aggregations, projections, dendrites, or asperities extending away from a major plane defined by the coating.

Techniques and systems according to the present disclosure may be used to plate an electrical contact on a substrate or a die, the electrical contact being compliant. The compliant electrical contact may allow electrical contacts or pads to be bonded together on non-planar or non-flat surfaces of substrates or dies, while exhibiting relatively high electrical contact. For example, compliance of the electrical contact may sustain and permit a degree of local deformation or deflection along the interface, which may promote contact between the surfaces along the interface and reduce gaps. The reduction in gaps and better contact may promote electrical contact between contacts or pads, reducing product rejection rates, and promoting process yield and reliability of bonding.

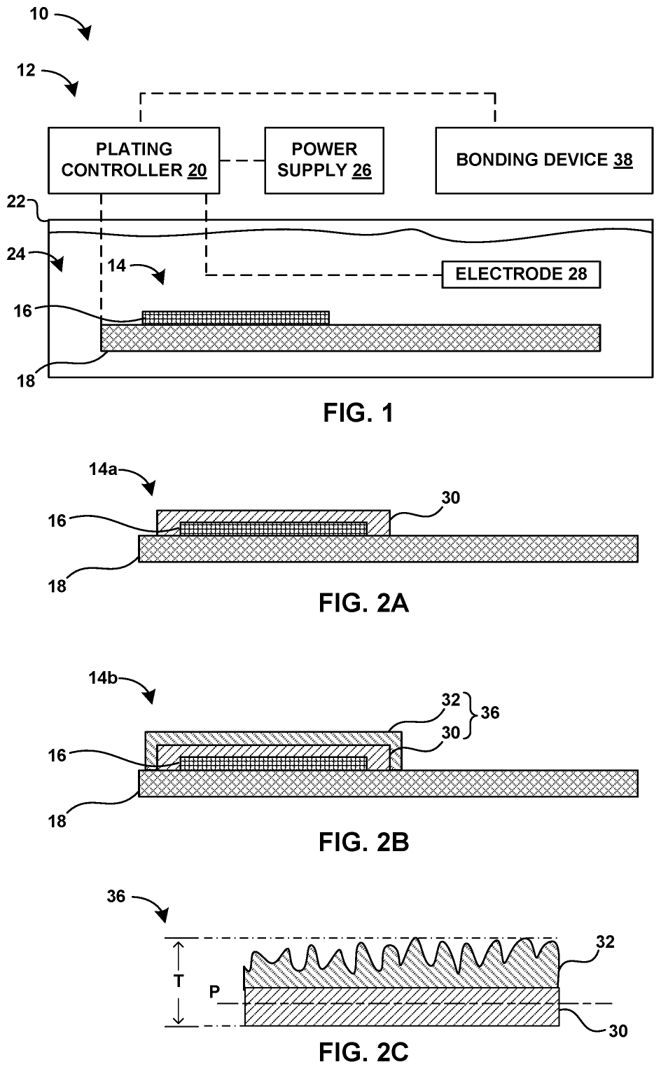

FIG. 1 is a block diagram of a system 10 including a plating apparatus 12 configured to form plating on an assembly 14 including an electrical contact 16 of a circuit substrate 18. Circuit substrate 18 may include a semiconductor substrate, semiconductor die, or some other substrate of an electronic component, for example, of an integrated circuit. Thus, circuit substrate 18 may include an integrated circuit die or an integrated circuit substrate.

Electrical contact 16 may include a seed layer or seed material, a wire bond pad, a solder bond pad, or any suitable contact pad or structure. Electrical contact 16 may be formed on circuit substrate 18 by any suitable technique, for example, sputtering, chemical vapor deposition, or physical vapor deposition. Electrical contact 16 may include any suitable metal or alloy, for example, one or more of nickel, copper, chromium, or gold.

Plating apparatus 12 is configured to plate a coating including a plating composition on electrical contact 16 of circuit substrate 18. Plating apparatus 12 may include a plating controller 20 and a housing 22. Housing 22 may include a carriage, frame, or holder securing assembly 14. Housing 22 may include an electrolytic composition 24. Electrolytic composition 24 may include at least one metal to be deposited on electrical contact 16, and further electrolytic components, for example, one or more of an acid, a buffer, a salt, or an additive. In some examples, electrolytic composition 24 includes one or more of gold, silver, platinum, palladium, rhodium, nickel, indium, copper, or tin. Electrolytic composition 24 may include a liquid, for example, a solution. Thus, the plating composition of the coating formed by plating apparatus is based on electrolytic composition 24, and process parameters applied by plating apparatus 12 to form the coating. In some examples, the plating composition includes at least one of gold, silver, platinum, palladium, rhodium, nickel, indium, copper, or tin. In some examples, the plating composition includes, consists of, or consists essentially of gold. For example, the plating composition may only include gold and minor impurities.

The coating may be formed by electrochemical deposition of metal from electrolytic composition 24 on electrical contact 16. For example, plating apparatus 12 may further include a power supply 26 and an electrode 28 coupled to plating controller 20, and plating controller 20 may apply an electric potential between assembly 14 and electrode 28. In some examples, electrode 28 is an anode, and assembly 14 acts as a cathode.

The electric potential applied between electrode 28 and assembly 14 causes metal to be deposited from electrolytic composition 24. The composition of electrolytic composition 24 may be selected to deposit a predetermined metal. For example, when electrolytic composition 24 includes gold, the gold from electrolytic composition 24 is deposited on electrical contact 16. Thus, plating apparatus 12 may deposit a coating on electrical contact 16 from electrolytic composition 24.

The properties of the coating may depend on one or more electrodeposition parameters, for example, cathode potential, anode potential, potential difference between the cathode and the anode, composition and geometry of electrode 28, composition and geometry of electrical contact 16, composition of electrolytic composition 24, and a current density within electrolytic composition 24.

Plating controller 20 may be configured to discharge a predetermined current from power supply 26 into electrolytic composition 24 to apply a predetermined current density. The current density may influence the structure of the coating deposited from electrolytic composition 24.

FIG. 2A is a partial cross-sectional view of assembly 14 in a first configuration 14a including electrical contact 16 and a first layer 30 plated on electrical contact 16. Plating controller 20 may be further configured to plate first layer 30 of a coating 36 on electrical contact 16 of circuit substrate 18 using a first current density. For example, the first current density may be in a range of from 0.5 to 0.8 amperes per square decimeter.

FIG. 2B is a partial cross-sectional view of assembly 14a of FIG. 2A in a second configuration 14b further including a second layer 32 on the first layer 30. Plating controller 20 may be further configured to plate second layer 32 of coating 36 on first layer 30 using a second current density that is higher than the first current density. The second current density may be greater than the first current density by a predetermined amount. For example, the second current density may be greater than the first current density by at least about 10%, by at least about 20%, by at least about 30%, by at least about 40%, by at least about 50%, by at least about 60%, by at least about 70%, by at least about 80%, by at least about 90%, by at least about 100%, by at least about 200%, or by at least about 300%. In some examples, the second current density is at least 50% greater than the first current density. In some examples, the second current density is at least 400% greater than the first current density.

The second current density higher than the first current density may promote the formation of a nodular deposit in second layer 32. For example, the second current density may exceed a predetermined threshold based on the plating composition, or may exceed the first current density by a threshold, to form the nodular deposit. Thus, second layer 32 may include a nodular deposit including the plating composition.

FIG. 2C is a partial magnified view of coating 36 including first layer 30 and second layer 32 of FIG. 2B, second layer 32 including the nodular deposit. The nodular deposit may include aggregations, projections, dendrites, or asperities extending away from a major plane P defined by the coating.

Coating 36 defines a coating thickness T, for example, in a direction transverse to major plane P defined by coating 36. The thickness T may be determined between maximum extremities of first layer 30 and second layer 32 transverse to major plane P. The coating thickness may be in any suitable range, for example, from 0.9 to 3.2 microns.

Second layer 32 may have any suitable thickness in a direction along coating thickness T. For example, second layer 32 may have a thickness that is at least 5%, at least 10%, at least 15%, at least 20%, at least 25%, at least 30%, at least 40%, at least 50%, at least 60%, or at least 70%, of coating thickness T. In some examples, second layer 32 has a thickness that is less than 80%, or less than 70%, or less than 60%, or less than 50%, or less than 40%, or less than 30%, or less than 20%, or less than 15%, or less than 10%, of the coating thickness. In some examples, second layer 32 has a thickness in a range from 10% to 80%, or 20% to 70%, or 25 to 75%, or 30% to 60%, of the coating thickness.

In some examples, plating apparatus 12 is configured to change the current density, for example, increase the current density, to terminate deposition of first layer 30 and initiate deposition of second layer 32. For example, plating apparatus 12 may be configured to increase the current density to the second current density when first layer 30 has a predetermined first layer thickness, so that second layer 32 including nodular deposit forms a remaining thickness of coating thickness T. In some examples, plating apparatus 12 may be configured to increase the current density to the second current density when first layer 30 in a range of from 25% to 75% of coating thickness T. Plating apparatus 12 may determine thickness of first layer 30 based on the duration of time and process parameters used to deposit first layer 30. For example, plating apparatus 12 may continue depositing first layer 30 using the first current density for a predetermined first plating time to provide a predetermined first layer thickness to first layer 30. Similarly, plating apparatus 12 may determine thickness of second layer 32 based on the duration of time and process parameters used to deposit second layer 32. For example, plating apparatus 12 may continue depositing first layer 32 using the second current density for a predetermined second plating time to provide a predetermined second layer thickness to first layer 32.

In some examples, coating 36 may include first layer 30, second layer 32, and at least one additional layer. For example, the at least one additional layer may include a further layer deposited on second layer 32, or a sub-layer deposited on electrical contact 16 prior to depositing first layer 30. In some examples, coating 36 does not include any layer other than first layer 30 or second layer 32. Thus, coating 36 may consist of, or consist essentially of, first layer 30 and second layer 32.

Plating apparatus 12 may be configured to plate second layer 32 integral with and continuously extending from first layer 30. For example, while an interface is shown between first layer 30 and second layer 32 in FIGS. 2B and 2C, no interface may be present between first layer 30 and second layer 32. In some examples, plating apparatus 12 may be configured to ramp current density from the first current density to the second current density so that second layer 32 continuously and integrally extends from first layer 30. Providing an integral transition between first layer 30 and second layer 32 may promote integrity of coating 36, and reduce or prevent formation of voids or gaps between first layer 30 and second layer 32.

Plating apparatus 12 may control the second current density to, in turn, control a nodularity of the nodular deposit. For example, in course of depositing second layer 32, plating controller 20 may be configured to increase or decrease the second current density in a manner to control the nodularity of second layer 32. For example, the nodularity may be characterized by geometric parameters, for example, one or more of an average length, a maximum length, an average diameter of nodular projections, a maximum cross-sectional diameter of nodular projections, average inter-projection spacing, or any other characteristic or combinations thereof. Plating controller 20 may vary the second current density to form the nodular deposit with predetermined characteristics. In other examples, plating controller 20 maintains the second current density substantially constant throughout deposition of second layer 32.

Turning back to FIG. 1, system 10 may further include a bonding device 38. Bonding device 38 may be configured to bond electrical contact 16 to another electrical contact. For example, circuit substrate 18 may be a first circuit substrate, and electrical contact 16 may be a first electrical contact. Bonding device 38 may be configured to bond the first electrical contact to a second electrical contact of a second circuit substrate. At least one of the first circuit substrate or the second circuit substrate defines a non-planar substrate surface. The nodular deposit is configured to cause the coating to be compliant relative to the non-planar substrate surface.

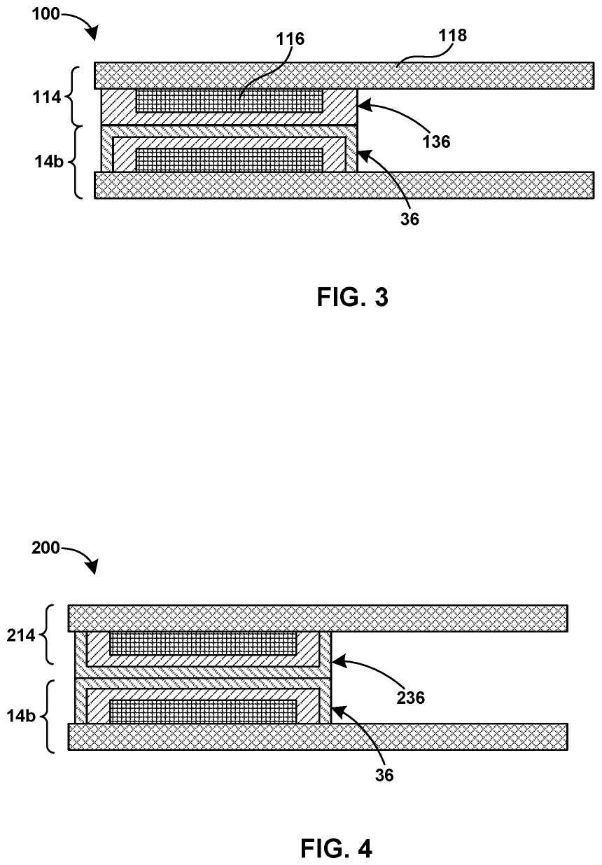

FIG. 3 is a partial cross-sectional view of an assembly 100 including first circuit assembly 14b including a nodular deposit bonded to a second circuit assembly 114 including a non-nodular plating. For example, first circuit assembly 14b may be substantially similar to assembly 14b described with reference to FIGS. 2B and 2C, including coating 36 including the nodular deposit. Second circuit assembly 114 may include a second electrical contact 116, a second circuit substrate 118, and a second coating 136. However, second coating 136 may not include a nodular deposit. The nodular deposit in first coating 36 may promote electrical contact between first circuit assembly 14 and second circuit assembly 114. For example, second circuit assembly 114 may exhibit non-planar features in second coating 136 (or in second electrical contact 116 or second circuit substrate 118), while still having an acceptable electrical contact with first circuit assembly 14 via the nodular deposit of coating 36. The presence of nodular deposit in first circuit assembly 14b may promote electrical connectivity between first circuit assembly 14b and second circuit assembly 114. For example, the nodular deposit may be sufficiently compliant to accommodate deformation resulting from the non-planar surfaces or features. In some examples, second circuit assembly 114 may not include second coating 136, and coating 36 may directly contact second electrical contact 116.

FIG. 4 is a partial cross-sectional view of an assembly 200 including a first circuit assembly 14b including a nodular deposit bonded to a second circuit assembly 214 including a nodular deposit. In assembly 200, second circuit assembly 214 is substantially similar to first circuit assembly 14b, and includes a second coating 236 including a nodular deposit. Thus, second circuit assembly 214 may be formed using similar techniques as described with reference to first circuit assembly 14b. The presence of nodular deposits in both first circuit assembly 14b and second circuit assembly 214 may promote electrical connectivity between first circuit assembly 14b and second circuit assembly 214. For example, one or both of first circuit assembly 14b and second circuit assembly 214 may exhibit non-planar surfaces or features, and the nodular deposit may be sufficiently compliant to accommodate deformation resulting from the non-planar surfaces or features.

Turning back to FIG. 1, system 10 may further include a computing device. For example, plating controller 20 may include the computing device, or the computing device may be in communication with controller 20. The computing device may perform one or more functions described with reference to plating controller 20.

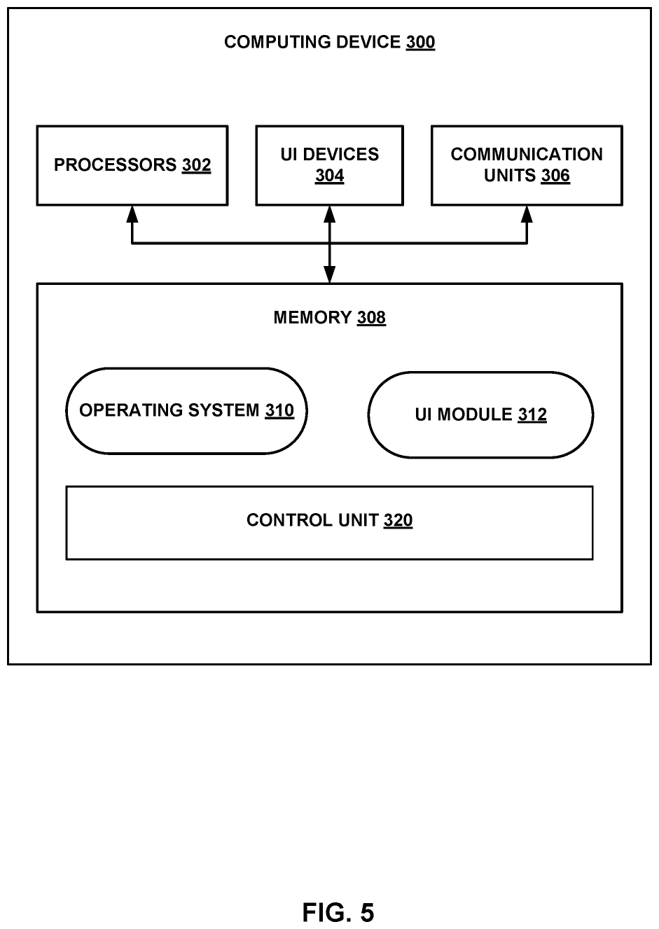

FIG. 5 is a block diagram illustrating computing device 300 configured to control plating apparatus 12. In some examples, computing device 300 may be an example instance of plating controller 20 of FIG. 1.

Computing device 300 includes one or more processors 302, one or more user interface (UI) devices 304, one or more communication units 306, and one or more memory units 308. Memory 308 of computing device 300 includes operating system 310, UI module 312, and control unit 320, which are executable by processors 302. Each of the components, units or modules of computing device 300 are coupled (physically, communicatively, and/or operatively) using communication channels for inter-component communications. In some examples, the communication channels may include a system bus, a network connection, an inter-process communication data structure, or any other method for communicating data.

Processors 302, in one example, may comprise one or more processors that are configured to implement functionality and/or process instructions for execution within computing device 300. For example, processors 302 may be capable of processing instructions stored by memory 308. Processors 302 may include, for example, processing circuitry, microprocessors, digital signal processors (DSPs), application specific integrated circuits (ASICs), field-programmable gate array (FPGAs), or equivalent discrete or integrated logic circuitry, or a combination of any of the foregoing devices or circuitry.

Memory 308 may be configured to store information within computing device 300 during operation. Memory 308 may include a computer-readable storage medium or computer-readable storage device. In some examples, memory 308 includes one or more of a short-term memory or a long-term memory. Memory 308 may include, for example, random access memories (RAM), dynamic random access memories (DRAM), static random access memories (SRAM), magnetic discs, optical discs, flash memories, or forms of electrically programmable memories (EPROM) or electrically erasable and programmable memories (EEPROM). In some examples, memory 308 is used to store program instructions for execution by processors 302. Memory 308 may be used by software or applications running on computing device 300 (e.g., control unit 320) to temporarily store information during program execution.

Computing device 300 may utilize communication units 306 to communicate with external devices via one or more networks or via wireless signals. Communication units 306 may be network interfaces, such as Ethernet interfaces, optical transceivers, radio frequency (RF) transceivers, or any other type of devices that can send and receive information. Other examples of interfaces may include Wi-Fi, NFC, or Bluetooth radios. In some examples, computing device 300 utilizes communication units 306 to wirelessly communicate with one or more external devices, such as plating apparatus 12, plating controller 20, power supply 26, or bonding device 38 of FIG. 1.

UI devices 304 may be configured to operate as both input devices and output devices. For example, UI devices 304 may be configured to receive tactile, audio, or visual input from a user of computing device 300. In addition to receiving input from a user, UI devices 304 may be configured to provide output to a user using tactile, audio, or video stimuli. In one example, UI devices 304 may be configured to output content such as a GUI for display at a display device. UI devices 304 may include a presence-sensitive display that displays a GUI and receives input from a user using capacitive, inductive, and/or optical detection at or near the presence sensitive display.

Other examples of UI devices 304 include a mouse, a keyboard, a voice responsive system, video camera, microphone or any other type of device for detecting a command from a user, or a sound card, a video graphics adapter card, or any other type of device for converting a signal into an appropriate form understandable to humans or machines. Additional examples of UI devices 304 include a speaker, a cathode ray tube (CRT) monitor, a liquid crystal display (LCD), organic light emitting diode (OLED), or any other type of device that can generate intelligible output to a user.

Operating system 310 controls the operation of components of computing device 300. For example, operating system 310, in one example, facilitates the communication of UI module 312 and control unit 320 with processors 302, UI devices 304, communication units 306, and memory 308. UI module 312 and control unit 320 may each include program instructions and/or data stored in memory 308 that are executable by processors 302. For example, control unit 320 may include instructions that cause computing device 300 to perform one or more of the techniques described in this disclosure.

Computing device 300 may include additional components that, for clarity, are not shown in FIG. 5. For example, computing device 300 may include a battery to provide power to the components of computing device 300. Similarly, the components of computing device 300 shown in FIG. 5 may not be necessary in every example of computing device 300.

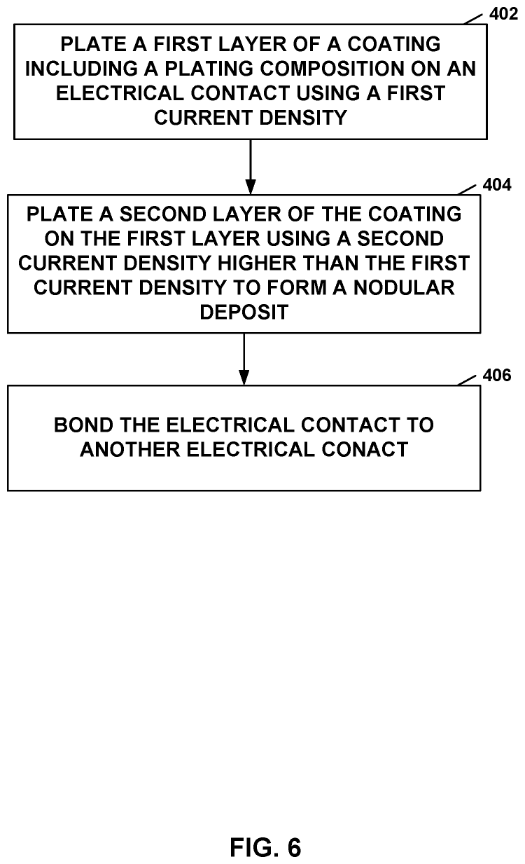

Control unit 320 may be configured to control system 10 and/or any of its components, for example plating apparatus 12, plating controller 20, or bonding device 20, and/or any other hardware or component of system 10. In some examples, control unit 320 may cause computing device 300 and/or processors 302 to execute one, more, or all portions of example techniques described in the present disclosure, for example, example techniques described with reference to FIG. 6.

FIG. 6 is a flowchart representing a technique for forming a plating on an electrical contact, for example, for integrated circuits and packages. While the technique of FIG. 6 is described with reference to components of system 10 described with reference to FIG. 1, any suitable system may be used to form the plating. Further, the technique of FIG. 6 may be performed by an operator, for example, manually, or semi-automatically. For example, the operator may control plating apparatus 12, plating controller 20, or computing device 300 to perform one or more steps of FIG. 6. In some examples, the technique of FIG. 6 may be performed automatically, for example, by plating controller 20 or computing device 300, based on predetermined instructions or programs.

In some examples, an example technique includes plating first layer 30 of coating 36 including a plating composition on electrical contact 16 of circuit substrate using 18 a first current density (402). The plating composition may include at least one of gold, silver, platinum, palladium, rhodium, nickel, indium, copper, or tin.

The technique may further include plating second layer 32 of coating 36 on first layer 30 using a second current density that is higher than the first current density (404). Second layer 32 may include a nodular deposit including the plating composition. In some examples, the second current density is at least 50% greater than the first current density. For example, the second current density may be at least 400% greater than the first current density.

Coating 36 may define coating thickness T, and the example technique may include forming second layer 32 (404) having a thickness in a range of 25 to 75% of coating thickness T.

Forming second layer 32 (404) may include forming second layer integral with and extending continuously from first layer 30. For example, the current density may be ramped from the first current density to the second current density such that second layer 32 continuously extends from first layer 30.

In some examples, circuit substrate 18 is a first circuit substrate, and electrical contact 16 is a first electrical contact. In some such examples, the technique further includes bonding the first electrical contact to a second electrical contact 116 of a second circuit substrate 118 (406). Second electrical contact 116 may include second coating 136, and second coating 136 may or may not include a nodular deposit. At least one of the first circuit substrate 18 or the second circuit substrate 18 defines a non-planar substrate surface. The nodular deposit is configured to cause coating 36 to be compliant relative to the non-planar substrate surface.

The following clauses illustrate example subject matter described herein.

Clause 1: A system including: a plating apparatus configured to plate a coating including a plating composition on an electrical contact of a circuit substrate; and processing circuitry configured to cause the plating apparatus to: plate a first layer of the coating on the electrical contact of the circuit substrate using a first current density; and plate a second layer of the coating on the first layer using a second current density that is higher than the first current density, where the second layer includes a nodular deposit including the plating composition.

Clause 2: The system of clause 1, where the second current density is at least 50% greater than the first current density.

Clause 3: The system of clauses 1 or 2, where the second current density is at least 400% greater than the first current density.

Clause 4: The system of any of clauses 1 to 3, where the circuit substrate includes an integrated circuit die or an integrated circuit substrate.

Clause 5: The system of any of clauses 1 to 4, where the plating composition includes at least one of gold, silver, platinum, palladium, rhodium, nickel, indium, copper, or tin.

Clause 6: The system of any of clauses 1 to 5, where the coating defines a coating thickness, and where the second layer has a thickness in a range of from 25% to 75% of the coating thickness.

Clause 7: The system of any of clauses 1 to 6, where the coating consists of the first layer and the second layer.

Clause 8: The system of any of clauses 1 to 6, where the processing circuitry is configured to cause the plating apparatus to plate the second layer integral with and continuously extending from the first layer.

Clause 9: The system of any of clauses 1 to 8, the system further including a bonding device, where the circuit substrate is a first circuit substrate, where the electrical contact is a first electrical contact, where at least one of the first circuit substrate or the second circuit substrate defines a non-planar substrate surface, and where the processing circuitry is further configured to cause the bonding device to bond the first electrical contact to a second electrical contact of a second circuit substrate.

Clause 10: The system of clause 9, where the nodular deposit is configured to cause the coating to be compliant relative to the non-planar substrate surface.

Clause 11: A method including: plating a first layer of a coating including a plating composition on an electrical contact of a circuit substrate using a first current density; and plating a second layer of the coating on the first layer using a second current density that is higher than the first current density, where the second layer includes a nodular deposit including the plating composition.

Clause 12: The method of clause 11, where the second current density is at least 50% greater than the first current density.

Clause 13: The method of clauses 11 or 12, where the second current density is at least 400% greater than the first current density.

Clause 14: The method of any of clauses 11 to 13, where the circuit substrate includes an integrated circuit die or an integrated circuit substrate.

Clause 15: The method of any of clauses 11 to 14, where the plating composition includes at least one of gold, silver, platinum, palladium, rhodium, nickel, indium, copper, or tin.

Clause 16: The method of any of clauses 11 to 15, where the coating defines a coating thickness, and where the second layer has a thickness in a range of 25 to 75% of the coating thickness.

Clause 17: The method of any of clauses 11 to 16, where the coating consists of the first layer and the second layer.

Clause 18: The method of any of clauses 11 to 17, where the second layer is integral with and extends continuously from the first layer.

Clause 19: The method of any of clauses 11 to 18, where the circuit substrate is a first circuit substrate, where the electrical contact is a first electrical contact, the method further including bonding the first electrical contact to a second electrical contact of a second circuit substrate, where at least one of the first circuit substrate or the second circuit substrate defines a non-planar substrate surface.

Clause 20: The method of clause 19, where the nodular deposit is configured to cause the coating to be compliant relative to the non-planar substrate surface.

The techniques described in this disclosure may be implemented, at least in part, in hardware, software, firmware, or any combination thereof. For example, various aspects of the described techniques may be implemented within one or more processors, including one or more microprocessors, digital signal processors (DSPs), application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry. A control unit including hardware may also perform one or more of the techniques of this disclosure.

Such hardware, software, and firmware may be implemented within the same device or within separate devices to support the various techniques described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware, firmware, or software components. Rather, functionality associated with one or more modules or units may be performed by separate hardware, firmware, or software components, or integrated within common or separate hardware, firmware, or software components.

The techniques described in this disclosure may also be embodied or encoded in an article of manufacture including a computer-readable storage medium encoded with instructions. Instructions embedded or encoded in an article of manufacture including a computer-readable storage medium, may cause one or more programmable processors, or other processors, to implement one or more of the techniques described herein, such as when instructions included or encoded in the computer-readable storage medium are executed by the one or more processors. Computer readable storage media may include random access memory (RAM), read only memory (ROM), programmable read only memory (PROM), erasable programmable read only memory (EPROM), electronically erasable programmable read only memory (EEPROM), flash memory, a hard disk, a compact disc ROM (CD-ROM), a floppy disk, a cassette, magnetic media, optical media, or other computer readable media. In some examples, an article of manufacture may include one or more computer-readable storage media.

In some examples, a computer-readable storage medium may include a non-transitory medium. The term “non-transitory” may indicate that the storage medium is not embodied in a carrier wave or a propagated signal. In certain examples, a non-transitory storage medium may store data that can, over time, change (e.g., in RAM or cache).

Various examples have been described. These and other examples are within the scope of the following claims.

What is claimed is:

1. A system comprising:
a plating apparatus configured to form a coating comprising a plating composition on an electrical contact of a circuit substrate; and
processing circuitry configured to cause the plating apparatus to:
plate a first layer of the coating on the electrical contact of the circuit substrate using a first current density; and
plate a second layer of the coating on the first layer using a second current density that is higher than the first current density,
wherein the second layer comprises a nodular deposit comprising the plating composition.

2. The system of claim 1, wherein the second current density is at least 50% greater than the first current density.

3. The system of claim 1, wherein the second current density is at least 400% greater than the first current density.

4. The system of claim 1, wherein the circuit substrate comprises an integrated circuit die or an integrated circuit substrate.

5. The system of claim 1, wherein the plating composition comprises at least one of gold, silver, platinum, palladium, rhodium, nickel, indium, copper, or tin.

6. The system of claim 1, wherein the coating defines a coating thickness, and wherein the second layer has a thickness in a range of from 25% to 75% of the coating thickness.

7. The system of claim 1, wherein the coating consists of the first layer and the second layer.

8. The system of claim 1, wherein the processing circuitry is configured to cause the plating apparatus to plate the second layer integral with and continuously extending from the first layer.

9. The system of claim 1, the system further comprising a bonding device, wherein the circuit substrate is a first circuit substrate, wherein the electrical contact is a first electrical contact, wherein at least one of the first circuit substrate or the second circuit substrate defines a non-planar substrate surface, and wherein the processing circuitry is further configured to cause the bonding device to bond the first electrical contact to a second electrical contact of a second circuit substrate.

10. The system of claim 9, wherein the nodular deposit is configured to cause the coating to be compliant relative to the non-planar substrate surface.

11. A method comprising:
plating a first layer of a coating comprising a plating composition on an electrical contact of a circuit substrate using a first current density; and
plating a second layer of the coating on the first layer using a second current density that is higher than the first current density,
wherein the second layer comprises a nodular deposit comprising the plating composition.

12. The method of claim 11, wherein the second current density is at least 50% greater than the first current density.

13. The method of claim 11, wherein the second current density is at least 400% greater than the first current density.

14. The method of claim 11, wherein the circuit substrate comprises an integrated circuit die or an integrated circuit substrate.

15. The method of claim 11, wherein the plating composition comprises at least one of gold, silver, platinum, palladium, rhodium, nickel, indium, copper, or tin.

16. The method of claim 11, wherein the coating defines a coating thickness, and wherein the second layer has a thickness in a range of from 25% to 75% of the coating thickness.

17. The method of claim 11, wherein the coating consists of the first layer and the second layer.

18. The method of claim 11, wherein the second layer is integral with and continuously extends from the first layer.

19. The method of claim 11, wherein the circuit substrate is a first circuit substrate, wherein the electrical contact is a first electrical contact, and wherein at least one of the first circuit substrate or the second circuit substrate defines a non-planar substrate surface, wherein the nodular deposit is configured to cause the coating to be compliant relative to the non-planar substrate surface, the method further comprising bonding the first electrical contact to a second electrical contact of a second circuit substrate.

20. An assembly comprising:
a circuit substrate; and
an electrical contact on a surface of the circuit substrate, the electrical contact comprising a coating comprising a plating composition,
wherein the coating comprises a first layer and a second layer extending from the first layer, the first layer between the electrical contact and the second layer, and
wherein the second layer comprises a nodular deposit comprising the plating composition.
